(19) United States
(12) Patent Application Publication
(10) Pub. No.: US 2025/0244686 A1
(43) Pub. Date: Jul. 31, 2025

(54) OPTICAL SYSTEM, LITHOGRAPHY MACHINE HAVING AN OPTICAL SYSTEM, AND METHOD FOR PRODUCING AN OPTICAL SYSTEM

(71) Applicant: Carl Zeiss SMT GmbH, Oberkochen (DE)

(72) Inventors: Sven URBAN, Neu-Ulm (DE); Florian ERMER, Heidenheim (DE)

(21) Appl. No.: 19/034,100

(22) Filed: Jan. 22, 2025

Related U.S. Application Data
(63) Continuation of application No. PCT/EP2023/070433, filed on Jul. 24, 2023.

(30) Foreign Application Priority Data
Jul. 25, 2022 (DE) 10 2022 207 555.2

(51) Int. Cl. G03F 7/00; H05K 3/46

(52) U.S. Cl. CPC G03F 7/70991; G03F 7/70841; G03F 7/7085; G03F 7/70891; G03F 7/7095; G03F 7/70975; H05K 3/4697

(57) ABSTRACT

An optical system for a lithography machine, comprising a circuit board made of a composite material. A vacuum-tight housing is formed by the composite material in an interior of the circuit board in which interior a number of active and/or passive components are arranged.

### CROSS-REFERENCE TO RELATED APPLICATIONS

The present application is a continuation of, and claims benefit under 35 USC 120 to, international application No. PCT/EP2023/070433, filed Jul. 24, 2023, which claims benefit under 35 USC 119 of German Application No. 10 2022 207 555.2, filed Jul. 25, 2022. The entire disclosure of each of these applications is incorporated by reference herein.

### FIELD

The present disclosure relates to an optical system, to a lithography apparatus having such an optical system and to a method for producing such an optical system.

### BACKGROUND

Microlithography is used for producing microstructured structural elements, such as for example integrated circuits. The microlithography process is carried out using a lithography apparatus that comprises an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range from 0.1 nm to 30 nm, such as 13.5 nm, are currently under development. Since most materials absorb light of this wavelength, such EUV lithography apparatuses typically use reflective optics, i.e. mirrors, instead of-as previously-refractive optics, i.e. lens elements.

A multiplicity of actuator/sensor devices, such as sensors and actuators, are installed in lithography apparatuses. In general, an actuator/sensor device is suitable for displacing an optical element, for example a mirror, assigned to the actuator/sensor device and/or for detecting a parameter of the assigned optical element, for instance a position of the assigned optical element or a temperature of the assigned optical element. For control and evaluation purposes, such an actuator/sensor device can be electrically connected to an electronic component, such as an integrated circuit (IC).

As a result of the optical elements of the lithography apparatus being situated in vacuo, the associated electronic parts are desirably be housed without vacuum contact in order to avoid cross contamination of the outgassing electronic parts. Electronic components regularly contain chemical elements that outgas in vacuo and can impair the properties of the optical elements.

A further reason for housing the electronic parts without vacuum contact lies in the fact that electronic parts generally contain certain proportions of gases that expand under the influence of the vacuum, and this may lead to defects of the electronics as a result. Therefore, the electronics can be housed in a protective atmosphere, in a manner insulated from the vacuum.

### SUMMARY

The present disclosure seeks to provide an improved optical system.

In an aspect, the disclosure provides an optical system for a lithography apparatus. The optical system has a printed circuit board that is formed from a composite material, wherein a vacuum-tight housing in which a number of active and/or passive components are arranged is formed in an interior region of the printed circuit board by the composite material.

The active and/or passive components can also be referred to as active and/or passive structural elements, silicon-based elements, electronic components or electronic parts. The printed circuit board can also be referred to as circuit board in the present case.

Embedding the vacuum-tight housing in the interior region of the printed circuit board can also allow the active and/or passive components to be housed in the vacuum housing of the optical system without being influenced by the adjacent/surrounding vacuum. In this case, the composite material of the printed circuit board can form the vacuum-tight housing, which can envelop the number of active and/or passive structural elements, such as in full and void of air.

Here, the electronic parts can be sealed from the vacuum as a result of the electronic parts being integrated in the printed circuit board. The electronic parts can be integrated in the compact, vacuum-tight housing which is placed in the printed circuit board interior. The fact that the vacuum-tight housing is formed by the composite material of the printed circuit board means that no additional dedicated housing may be required for the electronic parts.

Furthermore, optical lithography apparatuses can have very stringent parameters as a result of their physical properties, which inter alia can define and can restrict the installation spaces. Since the vacuum-tight housing is formed in the composite material of the printed circuit board, it can also be ultracompact for small installation spaces. The active and/or passive components that are embedded in the vacuum-tight housing of the printed circuit board in this case moreover can meet desired electrical properties which are locally inseparable or only separable with great difficulties.

As a result of an electronic logic that is based on the active and/or passive components being able to be installed in the vacuum housing in the tightest installation space and in the local vicinity of the optical elements of the lithography apparatus in this case, electrical signals can be processed further in the local vicinity. The reduction in needed signal path lengths and signal interfaces into and out of the system obtained as a result thereof can be beneficial with respect to the energy input and the signal-to-noise ratio.

Moreover, in applications, electrically converted signals can be provided for long transmission paths in the region of the vacuum using the components embedded in the printed circuit board.

Furthermore, the proposed printed circuit board with the integrated vacuum-tight housing for the electronic parts may require no additional mechanical separation elements between vacuum and non-vacuum; for example, it is possible to manage without the metal housings that are usually involved.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and refers to a wavelength of the operating light of between 0.1 nm and 30 nm. The projection exposure apparatus may also be a DUV lithography apparatus. DUV stands for “deep ultraviolet” and refers to a wavelength of the operating light of between 30 nm and 465 nm.

According to an embodiment, the number of active and/or passive components comprises an integrated circuit, a processor, a microprocessor, an FPGA, an analog-to-digital converter, a digital-to-analog converter, a transistor, more particularly a MOSFET, a silicon-based structural element, a capacitor, a resistor and/or an inductor.

According to an embodiment, the optical system comprises a vacuum housing in which the printed circuit board is arranged.

According to an embodiment, the vacuum housing is designed for a pressure of 1013.25 hectopascal (hPa) to 10⁻³ hPa in its interior. This pressure range can be referred to as normal pressure to fine vacuum.

According to an embodiment, the vacuum housing is designed for a pressure of 10⁻³ hPa to 10⁻⁸ hPa in its interior. This pressure range can be referred to as fine vacuum to high vacuum.

According to an embodiment, the vacuum housing is designed for a pressure of 10⁻⁸ hPa to 10⁻¹¹ hPa in its interior. This pressure range can be referred to as high vacuum to extreme-high vacuum.

According to an embodiment, the printed circuit board comprises at least one rigid region in which the vacuum-tight housing is formed by the composite material of the rigid region of the printed circuit board.

According to an embodiment, the printed circuit board comprises at least one rigid region in which the vacuum-tight housing is formed by the composite material of the rigid region of the printed circuit board and at least one pliable region.

According to an embodiment, the printed circuit board comprises two rigid regions, between which the pliable region is arranged. The pliable region of the printed circuit board may also be referred to as a flexible region.

The use of the pliable region of the printed circuit board can significantly increase the flexibility when the printed circuit board is installed in the lithography apparatus. This can be desirable, for example, when there are installation space restrictions within the lithography apparatus. Additionally, this can allow printed circuit boards to be installed in the lithography apparatus when in their bent state. This can reduce or prevent possible disturbances on components that are integrated in the printed circuit board or possible disturbances on electronic parts. Such possible disturbances comprise ambient influences and/or disturbances as a result of heat, coldness, mechanical disturbances and electromagnetic disturbances.

On account of the flexibility of the pliable printed circuit board, it is possible in applications to minimize the length of electrical lines that are used to connect the components provided in the housing of the printed circuit board to other structural elements, e.g. actuator/sensor devices. Such minimization of the length of the electrical lines can also reduce signal path lengths and hence can reduce the influence of possible disturbances within the scope of data transfer and control.

According to an embodiment, the pliable region of the printed circuit board is in a bent state when arranged, more particularly installed, in the optical system. In applications, such a bent state can be desirable with respect to installation space. Possible disturbances on an actuator/sensor device connected to the integrated circuit can be reduced or prevented as a result of the bent state.

According to an embodiment, the pliable region of the printed circuit board has a specific curvature and is in a bent state when arranged, for example installed, in the optical system, with the component arranged on the pliable region being arranged away from the specified curvature.

According to an embodiment, the printed circuit board comprises a plurality of N plies that form the composite material and comprise two outer plies and N−2 inner plies arranged between the two outer plies, wherein the vacuum-tight housing is formed in the region of the N−2 inner plies. The respective ply itself can be formed by a plurality of plies.

According to an embodiment, the N−2 inner plies are formed by an alternating sequence of metal layers or metal structures and insulator layers. For example, the metal layers are formed from copper. For example, the insulator layers are formed from a fiberglass substrate or from an epoxy resin.

According to an embodiment, the outer plies are formed as metal layers suitable for spreading heat.

The respective outer ply or layer can also be formed as an insulation layer, such as an outgassing-resistant plastic film, or as a lacquer.

According to an embodiment, the optical system further comprises at least one cooling structure that is embedded in the printed circuit board or at least one cooling structure that is applied to the printed circuit board. The cooling structure can be configured to dissipate heat that arises during the operation of the number of active and/or passive components arranged in the housing.

According to an embodiment, at least one conductor track of the printed circuit board is used to connect at least one of the number of active and/or passive components arranged in the vacuum-tight housing to at least one further active and/or passive component arranged externally to the vacuum-tight housing.

According to an embodiment, the optical system comprises a number of actuator/sensor devices, wherein at least one conductor track of the printed circuit board is used to connect at least one of the number of active and/or passive components arranged in the vacuum-tight housing to the number of actuator/sensor devices.

According to an embodiment, the optical system comprises a number of displaceable optical elements for guiding radiation in the optical system, wherein at least one of the actuator/sensor devices is assigned to the respective optical element and wherein the respective actuator/sensor device is configured to displace the assigned optical element and/or to detect a parameter of the assigned optical element, such as a position of the assigned optical element or a temperature in the region of the assigned optical element.

For example, the respective actuator/sensor device is an actuator (or actuating element) for actuating an optical element, a sensor for sensing an optical element or surroundings within the optical system, or an actuator and sensor device for actuating and sensing within the optical system. By way of example, the sensor is a temperature sensor. The actuator can be an actuator using the electrostrictive effect or an actuator using the piezoelectric effect, for example a PMN actuator (PMN; lead magnesium niobate) or a PZT actuator (PZT; lead zirconate titanate). The actuator is configured, for example, to actuate an optical element of the optical system. Examples of such an optical element include lens elements, mirrors and adaptive mirrors.

According to an embodiment, the optical system is in the form of an illumination optical unit or in the form of a projection optical unit of a lithography apparatus.

In an aspect, the disclosure provides a lithography apparatus, which comprises an optical system according to the disclosure.

In an aspect, the disclosure provides a method for producing an optical system for a lithography apparatus. The method comprises forming a printed circuit board from a composite material, in such a way that a vacuum-tight housing is formed by the composite material in an internal region of the printed circuit board, wherein a number of active and/or passive components are arranged in the housing while the printed circuit board is formed from the composite material.

The embodiments described for the proposed optical system apply correspondingly to the proposed method, and vice versa. Furthermore, the definitions and explanations in relation to the optical system also apply correspondingly to the proposed method.

“A (n)” should not necessarily be understood as a restriction to exactly one element in the present case. Instead, a plurality of elements, such as for example two, three or more, may also be provided. Nor should any other numeral used here be understood to the effect that there is a restriction to exactly the stated number of elements. Instead, unless indicated otherwise, numerical variances upward and downward are possible.

Further possible implementations of the disclosure also include combinations which have not been mentioned explicitly of features or embodiments described above or hereinafter with regard to the working examples. In this case, a person skilled in the art will also add individual aspects as improvements or supplementations to the respective basic form of the disclosure.

Further configurations and aspects of the disclosure are the subject of the dependent claims and of the exemplary embodiments of the disclosure that will be described hereinafter. The disclosure is elucidated in detail hereinafter on the basis of certain embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic illustration of an embodiment of an optical system;

FIG. 3 shows a schematic illustration of an embodiment of an optical system;

FIG. 4 shows a schematic illustration of an embodiment of a lithography apparatus; and

FIG. 5 shows a schematic view of an embodiment of a method for producing an optical system for a lithography apparatus.

### DETAILED DESCRIPTION

Unless indicated otherwise, elements that are identical or functionally identical have been provided with the same reference signs in the figures. It should also be noted that the illustrations in the figures are not necessarily true to scale.

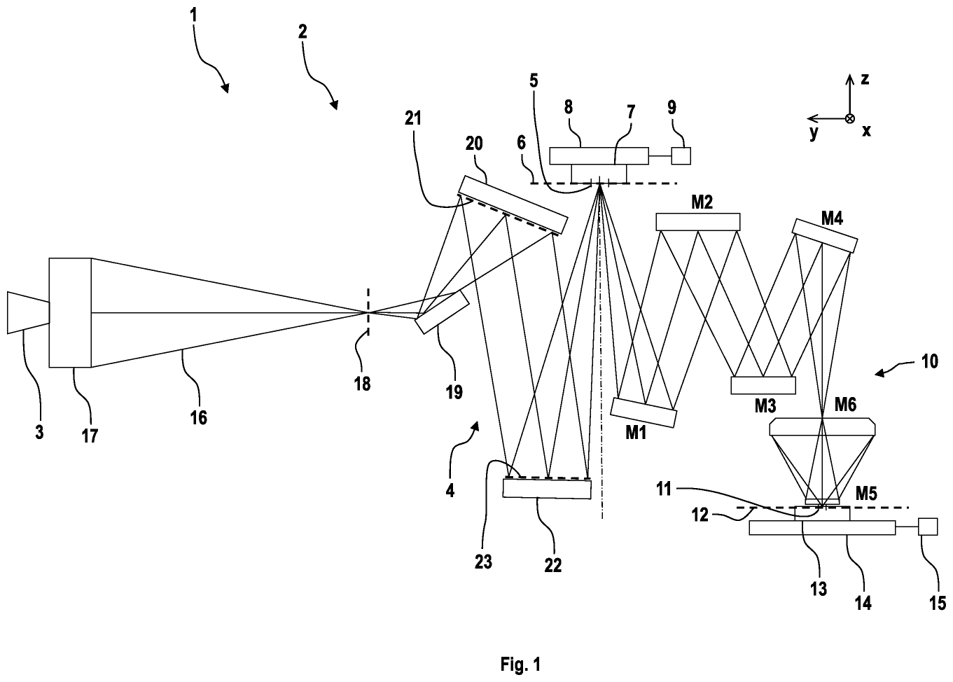

FIG. 1 shows one embodiment of a projection exposure apparatus 1 (lithography apparatus), such as an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not include the light source 3.

A reticle 7 arranged in the object field 5 is exposed. The reticle 7 is held by a reticle holder 8. The reticle holder 8 is displaceable by way of a reticle displacement drive 9, such as in a scanning direction.

FIG. 1 shows, by way of illustration, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, such as in the y-direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits EUV radiation 16, which is also referred to below as used radiation, illumination radiation or illumination light. For example, the used radiation 16 has a wavelength in the range between 5 nm and 30 nm. The light source 3 may be a plasma source, for example an LPP (laser produced plasma) source or a GDPP (gas discharge produced plasma) source. It can also be a synchrotron-based radiation source. The light source 3 may be a free electron laser (FEL).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond the pure deflection effect. In an alternative to that or in addition, the deflection mirror 19 can be designed as a spectral filter that separates a used light wavelength of the illumination radiation 16 from extraneous light at a different wavelength. If the first facet mirror 20 is arranged in a plane of the illumination optical unit 4 which is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be designed as macroscopic facets, such as rectangular facets or as facets with an arc-shaped edge contour or an edge contour of part of a circle. The first facets 21 may be designed as plane facets or alternatively as convexly curved or concavely curved facets.

As is known for example from DE 10 2008 009 600 A1, the first facets 21 themselves can also each be composed of a multiplicity of individual mirrors, such as a multiplicity of micromirrors. For example, the first facet mirror 20 can be in the form of a microelectromechanical system (MEMS system). For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is again made to DE 10 2008 009 600 A1.

The second facets 23 can have plane reflection surfaces or, alternatively, convexly or concavely curved reflection surfaces.

The illumination optical unit 4 thus forms a double-faceted system. This fundamental principle is also referred to as a fly's eye integrator.

It may be desirable to arrange the second facet mirror 22 not exactly within a plane that is optically conjugate to a pupil plane of the projection optical unit 10. For example, the second facet mirror 22 may be arranged so as to be tilted in relation to a pupil plane of the projection optical unit 10, as described for example in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing, for example, to the imaging of the first facets 21 into the object field 5 may be arranged in the beam path between the second facet mirror 22 and the object field 5. The transfer optical unit may have exactly one mirror or else, alternatively, two or more mirrors, which are arranged in succession in the beam path of the illumination optical unit 4. The transfer optical unit might comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi can be embodied as freeform surfaces without an axis of rotational symmetry. Alternatively, the reflection surfaces of the mirrors Mi may take the form of aspherical surfaces with exactly one axis of rotational symmetry of the reflection surface shape. Just like the mirrors of the illumination optical unit 4, the mirrors Mi may have highly reflective coatings for the illumination radiation 16. These coatings may take the form of multilayer coatings, for example with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y may be of approximately the same magnitude as a z-distance between the object plane 6 and the image plane 12.

The projection optical unit 10 may have an anamorphic design. It can have different imaging scales βx, βy in the x- and y-directions x, y. The two imaging scales βx, βy of the projection optical unit 10 can be (Bx, By)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may particular result in illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are each imaged onto the reticle 7 and overlaid over one another for the purpose of illuminating the object field 5. The illumination of the object field 5 is, for example, as homogeneous as possible. It can have a uniformity error of less than 2%. Field uniformity can be achieved by superimposing different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, such as the subset of the second facets 23, which guide light. This intensity distribution is also referred to as illumination setting or illumination pupil filling.

A likewise preferred pupil uniformity in the region of sections of an illumination pupil of the illumination optical unit 4 that are illuminated in a defined manner may be achieved by a redistribution of the illumination channels.

Further aspects and details of the illumination of the object field 5 and for example of the entrance pupil of the projection optical unit 10 are described hereinafter.

The projection optical unit 10 can have a homocentric entrance pupil, for example. It may be accessible. It may also be inaccessible.

The entrance pupil of the projection optical unit 10 regularly cannot be exactly illuminated with the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. For example, this area exhibits a finite curvature.

It may be the case that the projection optical unit 10 has different positions of the entrance pupil for the tangential beam path and for the sagittal beam path. In this case, an imaging element, such as an optical structural element of the transfer optical unit, should be provided between the second facet mirror 22 and the reticle 7. With the aid of this optical element, the different positions of the tangential entrance pupil and the sagittal entrance pupil may be taken into account.

In the arrangement of the component parts of the illumination optical unit 4 illustrated in FIG. 1, the second facet mirror 22 is arranged in an area conjugate to the entrance pupil of the projection optical unit 10. The first facet mirror 20 is in a tilted arrangement in relation to the object plane 6. The first facet mirror 20 is in a tilted arrangement in relation to an arrangement plane defined by the deflection mirror 19. The first facet mirror 20 is in a tilted arrangement in relation to an arrangement plane defined by the second facet mirror 22.

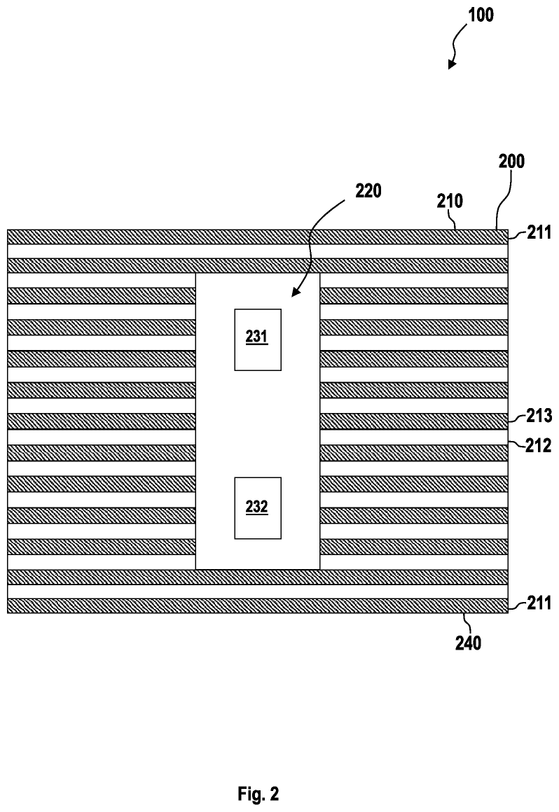

FIG. 2 shows a schematic illustration of an embodiment of an optical system 100 for a lithography apparatus or projection exposure apparatus 1, as shown in FIG. 1 for example. Additionally, the optical system 100 of FIG. 2 may also be used in a DUV lithography apparatus for example.

The optical system 100 comprises a printed circuit board 200. The printed circuit board 200 is formed from a composite material 210. A vacuum-tight housing 220 is formed in the interior region of the printed circuit board 200 by the composite material 210. A number of active and/or passive components 231, 232 are arranged in the vacuum-tight housing 220.

In the example of FIG. 1, the printed circuit board 200 has a rigid region 240 in which the vacuum-tight housing 220 is formed by the composite material 210 of the rigid region 240.

For example, the number of active and/or passive components 231, 232 comprises an integrated circuit, a processor, a microprocessor, an FPGA (field programmable gate array), an analog-to-digital converter, a digital-to-analog converter, a transistor, for example a MOSFET, a capacitor, a resistor, an inductor and/or a circuit made of these elements. The respective component 231, 232 can also be embodied as a structural element or electronic structural element.

The printed circuit board 200 has a plurality of N plies 211, 212, 213 (with N≥5 for example) that form the composite material 210 and comprise two outer plies 211 and N−2 inner plies 212, 213 arranged between the two outer plies 211.

Without loss of generality, N=25 in FIG. 2. The N−2 inner plies 212, 213, accordingly the 23 inner plies in FIG. 2, are formed by an alternating sequence of metal layers 212 and insulator layers 213. In this case, an inner layer without hatching is a metal layer 212 in FIG. 2, and an inner layer with hatching is an insulator layer 213. For reasons of clarity, only one respective metal layer 212 and one respective insulator layer 213 has been provided with a reference sign.

For example, the metal layers 212 are formed from copper. For example, the insulator layers 213 are formed from a fiberglass substrate and/or from an epoxy resin. The two outer layers 211 (the uppermost layer and the lowermost layer in FIG. 2, provided with reference sign 211) are embodied as an insulator layer by way of example and can be embodied as an outgassing-resistant plastic film.

The outer layers 211 can also be formed as a lacquer or as a metal layer suitable for spreading heat. For the latter example, the side flanges of the printed circuit board 200 (not shown in FIG. 2) might also be provided with a metal layer suitable for spreading heat.

A cooling structure (not shown) can also be embedded in the printed circuit board 200 and is configured to dissipate heat that arises during the operation of the number of active and/or passive components 231, 232 arranged in the housing 220.

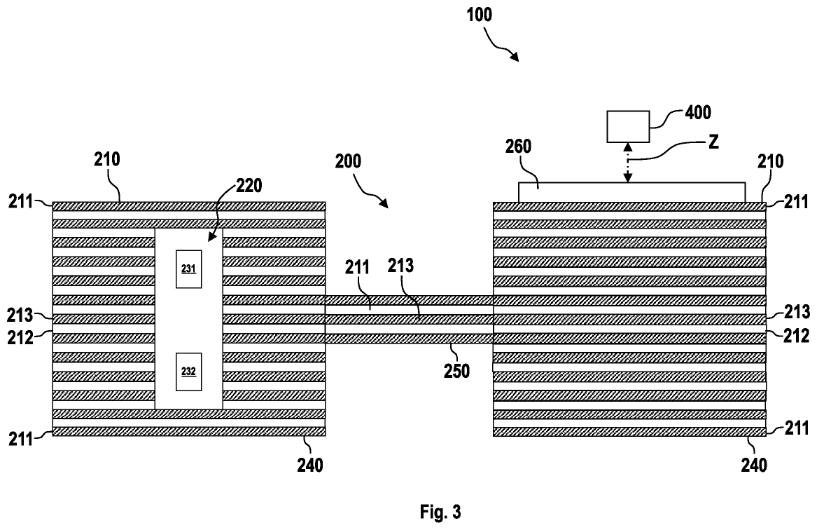

FIG. 3 shows a schematic illustration of a second embodiment of an optical system 100. The optical system 100 according to FIG. 3 comprises a printed circuit board 200 which comprises two rigid regions 240 and a flexible region 250. In this case, the flexible region 250 connects the left rigid region 240 and the right rigid region 240 of the printed circuit board 200. The left rigid region 240 is embodied as shown in FIG. 2 and described above. The right rigid region 240—like the left rigid region 240—comprises a composite material 210 made of a plurality of N plies 211, 212, 213 that form the composite material 210.

As already described in relation to FIG. 2, the inner layers of the printed circuit board 200 without hatching are metal layers 212 and the inner layers of the printed circuit board 200 with hatching are insulator layers 213. Like in FIG. 2, only a few of the inner layers in FIG. 3 have been provided with the corresponding reference sign, 212 for a metal layer and 213 for an insulator layer, for reasons of clarity.

Moreover, the optical system 100 according to FIG. 3 has an actuator/sensor device 260 for an optical element 400. The actuator/sensor device 260 according to FIG. 3 is electrically connected to the right rigid region 240 of the printed circuit board 200 and is more particularly arranged on this right rigid region 240. Alternatively, the element 260 can also be an interface or a plug.

For example, the actuator/sensor device 260 is a temperature sensor or an actuator. In general, the actuator/sensor device 260 is configured to detect a parameter of an assigned optical element 400, for example a temperature in the region of the assigned optical element 400 or a position of the assigned optical element 400, and/or to displace the assigned optical element 400. For example, the optical element 400 is one of the mirrors M1 to M6 or one of the facet mirrors 20 to 23.

In FIG. 3, the assignment between the actuator/sensor device 260 and the optical element 400 is indicated by the dashed arrow provided with reference sign Z.

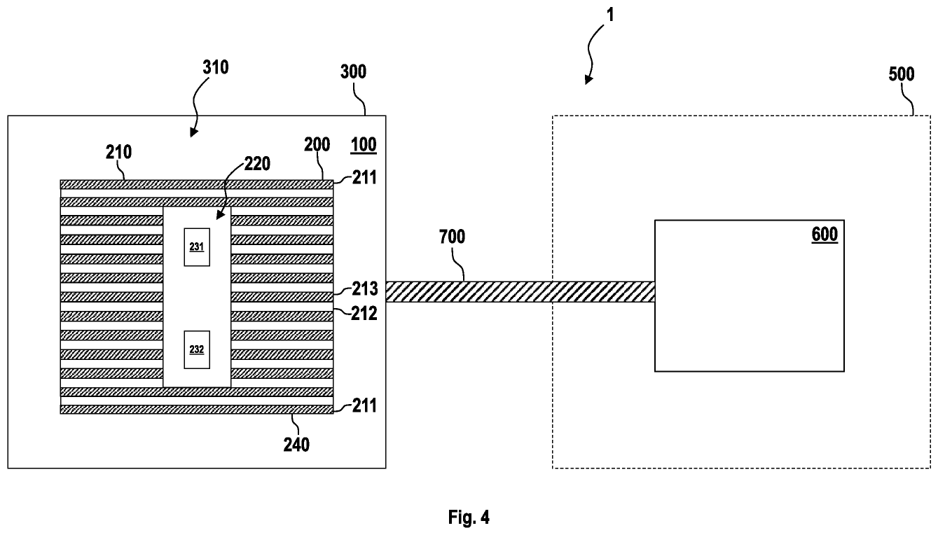

FIG. 4 shows a further embodiment of a projection exposure apparatus 1 (lithography apparatus), such as an EUV lithography apparatus. The lithography apparatus 1 according to FIG. 4 has a vacuum housing 300, in the interior 310 of which an optical system 100 is arranged. In the example of FIG. 4, the optical system 100 is formed as shown in FIG. 2. Alternatively, the optical system 100 of FIG. 4 can be formed as shown in FIG. 3.

The vacuum housing 300 of FIG. 4 can be designed for a pressure of 1013.25 hPa to 10⁻³ hPa in its interior 310. Alternatively, the vacuum housing 300 can also be designed for a pressure of 10⁻³ hPa to 10⁻⁸ hPa in its interior 310. In a further alternative, the vacuum housing 300 can also be designed for a pressure of 10⁻⁸ hPa to 10⁻¹¹ hPa in its interior 310.

As illustrated in FIG. 4, the lithography apparatus 1 also contains a non-vacuum region 500 in addition to the vacuum housing 300. The non-vacuum region 500 is a region or a space outside of the vacuum housing 300. A piece of electronic equipment 600, for example in the form of a piece of control equipment and/or a piece of transceiver equipment, is arranged in this non-vacuum region 500.

In the example of FIG. 4, the printed circuit board 200 is coupled with the electronic equipment 600, such as for data interchange, by way of at least one electric line 700.

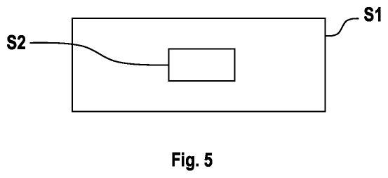

FIG. 5 shows a schematic view of an embodiment of a method for producing an optical system 100 for a lithography apparatus 1. Examples of the optical system 100 are illustrated in FIGS. 2 and 3.

An example of a lithography apparatus 1 having an optical system 4, 10 is depicted in FIG. 1, and a further example of a lithography apparatus 1 having an optical system 100 is depicted in FIG. 4.

The embodiments of the method according to FIG. 5 comprises forming S1 a printed circuit board 200 from a composite material 210, in such a way that a vacuum-tight housing 220 is provided by the composite material 210 in an interior of the printed circuit board 200. While the printed circuit board 200 is formed S1 from the composite material 210, a number of active and/or passive components 231, 232 are arranged in the housing 220 according to step S2. Consequently, step S2, specifically arranging a number of active or passive components 231, 232 in the housing 220, is a part of step S1 of forming the printed circuit board 200.

As already explained with reference to FIGS. 2 and 3, the printed circuit board 200 is formed by a plurality of N plies 211, 212, 213, which form the composite material 210. The N plies 211, 212, 213 comprise two outer plies 211 and N−2 inner plies 212, 213 arranged between the two outer plies 211. As illustrated in FIGS. 2 and 3, the vacuum-tight housing 220 is formed in the region of the N−2 inner plies 212, 213.

Although the present disclosure has been described on the basis of exemplary embodiments, it can be modified in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
200 Printed circuit board
210 Composite material
211 Outer ply
212 Inner ply, a metal layer for example
213 Inner ply, an insulator layer for example
220 Vacuum-tight housing
231 Component
232 Component
240 Rigid region of the printed circuit board
250 Pliable region of the printed circuit board
260 Actuator/sensor device
300 Vacuum housing
310 Interior of the vacuum housing
400 Optical element
500 Non-vacuum region
600 Electronic equipment
700 Electrical line
M1 Mirror
M2 Mirror
M3 Mirror
M4 Mirror
M5 Mirror
M6 Mirror
S1 Method step
S2 Method step
Z Assignment

What is claimed is:

1. An optical system, comprising:
a printed circuit board comprising a composite material,
wherein:
the composite material defines a vacuum-tight housing in an interior region of the printed circuit board; and
a number of active and/or passive components are disposed within the vacuum-tight housing.

2. The optical system of claim 1, wherein the number of active and/or passive components comprises at least one member selected from the group consisting of an integrated circuit, a processor, a microprocessor, an FPGA, an analog-to-digital converter, a digital-to-analog converter, a transistor, more particularly a MOSFET, a capacitor, a resistor, and an inductor.

3. The optical system of claim 1, wherein:
the printed circuit board comprises a rigid region comprising the composite material; and
the composite material of the rigid region defines the vacuum-tight housing.

4. The optical system of claim 1, wherein the printed circuit board further comprises a pliable region.

5. The optical system of claim 4, wherein:
the printed circuit board comprises a rigid region comprising the composite material;
the composite material of the rigid region defines the vacuum-tight housing;
the printed circuit board further comprises a further rigid region; and
the pliable region connects the rigid region and the further rigid region.

6. The optical system of claim 1, wherein:
the composite material comprises a plurality of plies;
the plurality of plies comprises two outer plies and inner plies between the two outer plies; and
the inner plies define the vacuum-tight housing.

7. The optical system of claim 6, wherein:
the inner plies comprise an alternating sequence of metal layers and insulator layers; and
the two outer plies comprise metal layers configured to spread heat.

8. The optical system of claim 1, further comprising a cooling structure embedded in the printed circuit board, wherein the cooling structure is configured to dissipate heat from the number of active and/or passive components.

9. The optical system of claim 1, wherein the printed circuit board comprises a conductor track connecting at least one of the number of active and/or passive components to at least one further active and/or passive component outside the vacuum-tight housing.

10. The optical system of claim 1, further comprising a number of actuator/sensor devices, wherein the printed circuit board comprises at least one conductor track connecting at least one of the number of active and/or passive components to at least one of the number of actuator/sensor devices.

11. The optical system of claim 1, wherein:
the printed circuit board comprises a rigid region comprising the composite material;
the composite material of the rigid region defines the vacuum-tight housing
the printed circuit board further comprises a pliable region and a further rigid region;
the pliable region connects the rigid region and the further rigid region;
the composite material comprises a plurality of plies;
the plurality of plies comprises two outer plies and inner plies between the two outer plies; and
the inner plies define the vacuum-tight housing.

12. The optical system of claim 11, wherein:
the inner plies comprise an alternating sequence of metal layers and insulator layers; and
the two outer plies comprise metal layers configured to spread heat.

13. The optical system of claim 11, further comprising a cooling structure embedded in the printed circuit board, wherein the cooling structure is configured to dissipate heat from the number of active and/or passive components.

14. The optical system of claim 11, further comprising a number of actuator/sensor devices, wherein the printed circuit board comprises at least one conductor track connecting at least one of the number of active and/or passive components to at least one of the number of actuator/sensor devices.

15. An apparatus, comprising:
an optical system according to claim 1,
wherein the apparatus is a lithography apparatus.

16. The apparatus of claim 15, wherein the optical system is an illumination optical unit or a projection optical unit.

17. The apparatus of claim 15, wherein the apparatus comprises a vacuum housing, and the printed circuit board is disposed within the vacuum housing.

18. The apparatus of claim 17, wherein the vacuum housing is configured for an interior pressure in a range selected from the group consisting of from 1013.25 hectopascal (hPa) to 10⁻³ hPa, from 10⁻³ to 10⁻⁸ hPa, and from 10⁻⁸ to 10⁻¹¹ hPa.

19. A method of making an optical system of a lithography apparatus, the method comprising:
forming a printed circuit board from a composite material so that the composite material defines a vacuum-tight housing in an internal region of the printed circuit board, wherein a number of active and/or passive components are disposed in a region within the composite material while the printed circuit board is being formed from the composite material.

20. The method of claim 19, wherein:
the composite material comprises a number of plies;
the number of plies comprises two outer plies and inner plies between the two outer plies; and
the vacuum-tight housing is disposed within the inner plies.
